(19) United States
(12) Patent Application Publication
(10) Pub. No.: US 2020/0176365 A1
(43) Pub. Date: Jun. 4, 2020

(54) INTEGRATED CIRCUIT PACKAGE WITH LEAD LOCK

(71) Applicant: Texas Instruments Incorporated, Dallas, TX (US)

(72) Inventors: Bin Abdul Aziz Anis Fauzi, Batu Berendam (MY); Wei Fen Sueann Lim, Melaka (MY); Lee Han Meng@Eugene Lee, Muar (MY)

(21) Appl. No.: 16/782,824

(22) Filed: Feb. 5, 2020

Related U.S. Application Data
(63) Continuation of application No. 15/858,643, filed on Dec. 29, 2017.

(51) Int. Cl. H01L 23/495; H01L 21/48; H01L 21/56; H01L 23/00; H01L 23/31

(52) U.S. Cl. CPC H01L 23/49555; H01L 2224/45124; H01L 21/565; H01L 24/85; H01L 23/49503; H01L 24/48; H01L 23/3121; H01L 23/49548; H01L 2224/48463; H01L 2224/48091; H01L 2224/48247; H01L 2924/35121; H01L 2924/14; H01L 2224/45144; H01L 23/49541; H01L 24/45; H01L 2224/45147; H01L 21/4842

(57) ABSTRACT

In a described example, a packaged integrated circuit (IC) includes a lead frame with a lead and with an IC chip mount pad. A portion of the lead adjacent to the IC chip mount pad is mechanically deformed to form a lead lock. An integrated circuit chip is mounted on a first side of the IC chip mount pad; and the integrated circuit chip, the IC chip mount pad, and the portion are covered in molding compound.

This application is a continuation to U.S. patent application Ser. No. 15/858,643, filed Dec. 29, 2017, the contents of which are herein incorporated by reference in its entirety.

### TECHNICAL FIELD

This disclosure relates generally to integrated circuit packaging, and more particularly to lead locks in packaged integrated circuit devices.

### BACKGROUND

The most widely used integrated circuit (IC) package is a lead frame (LF) based package. The LF typically includes a chip mount pad for attaching the IC chip, and a plurality of leads to connect to external circuits. Gaps between the “inner” end or a head of the leads and bond pads on an IC mounted to the LF are typically connected by thin metallic bond wires (typically made of gold, copper, aluminum, or an alloy thereof) which are individually bonded to bond pads on the IC and bonded to the leads. The LF is often conductive metal. The outer ends of the leads are configured to be electrically and mechanically connected to a printed circuit board (PCB). After attaching the IC chip to the chip mount pad on the lead frame, the IC chip, the bond wires, and a portion of the leads are encapsulated with molding compound (MC). In some examples, a strip of lead frames coupled together and carrying IC chips on chip mount pads is placed in a mold tool as one unit, and molding is performed with the MC forming around each lead frame and IC chip, while portions of lead frame material between the IC chips connect the devices during molding. The lead frame strip is then removed from the mold tool and the individual devices are then singulated to complete the IC packaging process. The ends of the leads are not encased with MC during the encapsulation, instead these ends of the leads extend outward from the package formed by the MC and provide electrical terminals and surfaces for electrical connection and physical attachment for the completed packaged IC.

As the packaged IC undergoes temperature cycling, e.g. during device reliability testing and during device usage, thermomechanical stresses are induced at the joints and interfaces between dissimilar materials used in the IC assembly and packaging process. For example, the metal lead frame expands and contracts differently than the plastic MC thereby causing stress and possible delamination at the joints and interfaces. These stresses, which may be repeatedly induced during hundreds or thousands of temperature cycles, tend to fatigue the joints and interfaces, and may result in cracking and eventual failure of the packaged IC.

Lead lock structures are formed on the leads by adding patterning and etching steps during lead frame manufacture. The lead lock structures add texture and topography to the portion of the lead frame adjacent to the chip mount pad that is later encapsulated with MC. Patterning and etching manufacturing steps to form the lead lock structures add cost to the packaged IC.

In addition, as integrated circuit packages are continuously scaled smaller, the scaled leads become less robust. The removal of metal during lead lock formation additionally weakens the leads increasing susceptibility to fatigue and failure.

### SUMMARY

In a described example, a packaged integrated circuit (IC) includes a lead frame with a lead and with an IC chip mount pad. A portion of the lead adjacent to the IC chip mount pad is mechanically deformed to form a lead lock. An integrated circuit chip is mounted on a first side of the IC chip mount pad; and the integrated circuit chip, the IC chip mount pad, and the portion are covered in molding compound.

### BRIEF DESCRIPTION OF THE DRAWINGS

FIG. 1 is a projection view of a lead frame.

FIG. 2 is a projection view of a lead.

FIG. 3 illustrates a packaged integrated circuit chip.

FIG. 4 is a projection view of portions of a lead frame.

FIG. 5 illustrates an integrated circuit chip flip chip mounted to a lead frame.

FIG. 6 shows an example lead lock structure using a waffle pattern on a lead.

FIG. 7 shows an example lead lock structure using a dimple pattern on a lead.

FIG. 8 shows an example lead lock structure using a semicircular trench formed on a lead.

FIG. 9 shows an example lead lock structure using a semicircular trench and a raised portion on a lead.

FIG. 10 shows an example lead lock structure on a lead with a rectangular trench and a v-groove.

FIG. 11 shows an example lead lock structure with a plurality of vertical v-grooves in vertical sides of a lead.

FIG. 12 shows an example lead lock structure with a semicircular trench stamped into the bottom of a lead.

FIG. 13 shows example leads with additional lead lock structures including semicircular structures on sides of a portion of a lead.

FIG. 14 shows an example lead frame with adhesion promoting structures.

FIG. 15 is a flow diagram of a method for forming an integrated circuit package with lead locks.

### DETAILED DESCRIPTION

Corresponding numerals and symbols in the different figures generally refer to corresponding parts unless otherwise indicated. The figures are not necessarily drawn to scale.

Portions of leads are described herein as “straight”. A straight element is an element that extends uniformly in one direction without bends or cures. Portions of leads are also described herein as “curved”. A curved element is an element that deviates from a straight course in a smooth or continuous fashion. In some examples, the curve follows an “S” shape. Leads useful with the arrangement can follow other shapes, or may be straight from end to end with no curved portion. A first straight segment can be connected to a second straight segment by a sloped, or curved, segment. Portions of elements are described herein as “coplanar”. Coplanar elements are elements that lie in the same plane.

During manufacture, some slight deviation of surfaces may occur. However, as used herein, elements that are intended to be straight, curved or coplanar without these manufacturing deviations are “straight”, “curved” and “coplanar” as the terms are used herein, even if slight manufacturing deviations occur.

In the description that follows, some structures are described as “T-shaped”. A structure is T-shaped when an end portion extends in one direction and a second portion that intersects and connects to the end portion in a middle part of the end portion extends away from the intersection in a second direction that is at a ninety degree angle to the first direction. During manufacturing, the resulting angle may deviate somewhat from ninety degrees, but if the angle is intended to be ninety degrees without manufacturing variances, the structure is still T-shaped.

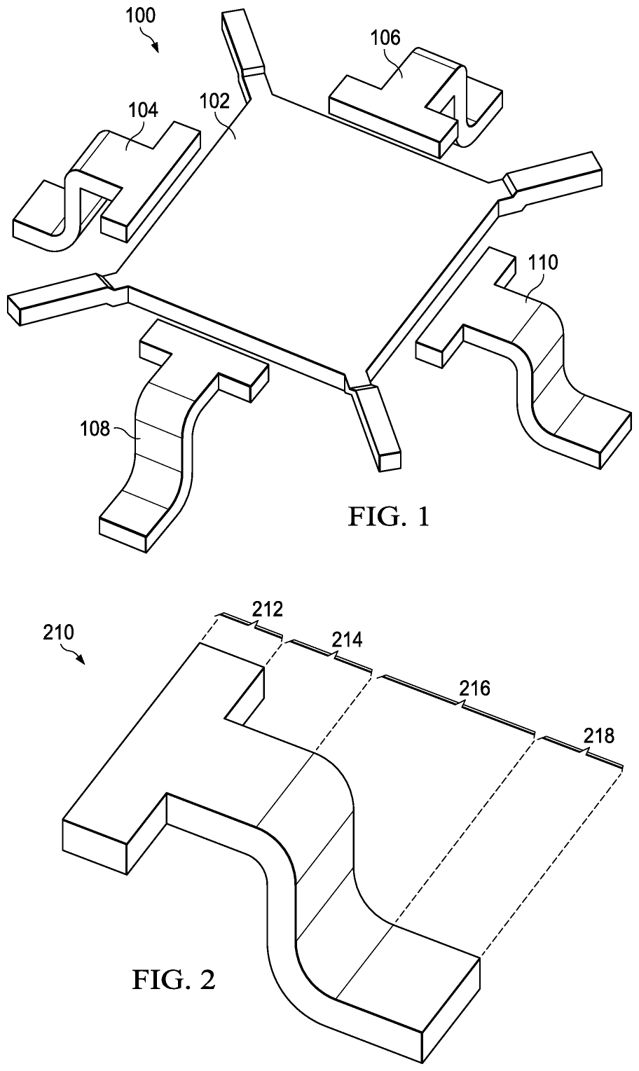

FIG. 1 illustrates a projection view of an example lead frame 100. Lead frame 100 consists of a centrally located chip mount pad 102 surrounded by leads, 104, 106, 108, and 110. The number of leads is partly determined by the number of bond pads on an IC chip. In some examples, the number of leads may be less than, or greater than, the number of bond pads, some bond pads are not connected to leads. In some other examples leads can be used for other purposes than connecting to a bond pad. Four leads are used in FIG. 1 for illustration. The number of leads can be more than shown in FIG. 1. In this example, the leads are T-shaped. A gap separates the head of the individual leads 104, 106, 108, 110 from the chip mount pad 102.

FIG. 2 illustrates in an expanded projection view a lead 210. In FIG. 2, similar reference labels are used for similar elements shown in FIG. 1, for clarity. For example, lead 210 in FIG. 2 corresponds to lead 110 in FIG. 1. The lead 210 is T shaped. The head 212 of the lead 210 (top cross bar of the T as oriented in FIG. 2) is separated from the chip mount pad (not in FIG. 2, see 110 and 102 in FIG. 1) by a gap. The tail of the lead 210 extends away from the head 212. In this example arrangement, the tail of the lead 210 is comprised of a first straight segment 214 which is attached to the head 212, a middle segment 216, which in this example is a curved “S” shaped segment with a first end connected to the first straight segment 214 and with a second end connected to a second straight segment 218. As oriented in FIG. 2, the first end of the curved S shaped segment 216 forms an upper end, and as shown in FIG. 2, the second end of the curved S shaped segment 216 is below the upper end, or forms a lower end. In alternative arrangements the middle segment can be other shapes. The second straight segment 218 is in a plane below (as oriented in FIG. 2) and parallel to the first straight segment 214. The second straight segment 218 is connected to the first straight segment 214 by the curved “S” shaped segment 216, but does not underlie (as oriented in FIG. 2) the first straight segment 214. In other example arrangements, the leads may have a curved segment that is differently shaped, or the first straight segment may be joined to the second straight segment by another straight segment, or by a sloped segment.

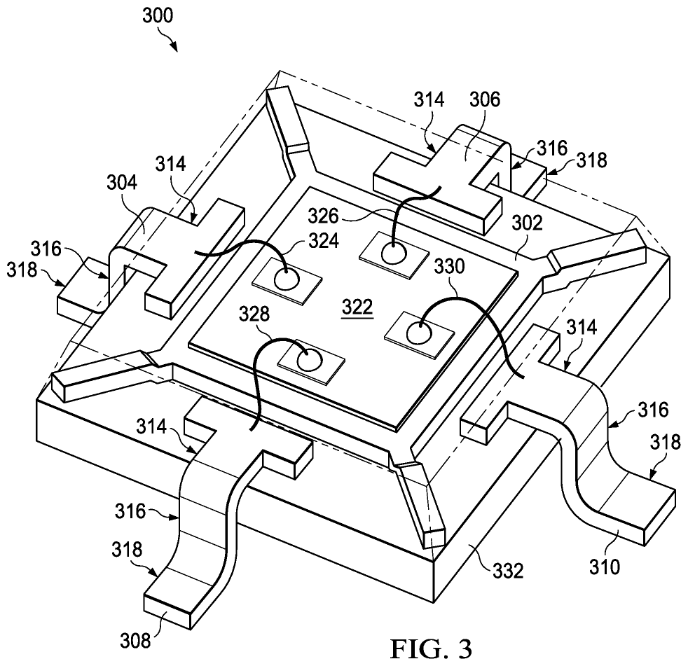

FIG. 3 illustrates in a projection view a packaged IC chip 300. In FIG. 3, similar reference labels are used for similar elements shown in FIG. 1. For example, lead 310 in FIG. 3 corresponds to lead 110 in FIG. 1. IC chip 322 is mounted on the chip mount pad 302. Bond wires 324, 326, 328, and 330 attached to bond pads on the IC chip 322 are stitch bonded to the heads of leads, 304, 306, 308, and 310, respectively. The bond wires may be ball bonded on the bond pads of IC chip 322, and stitch bonded on the leads using a “ball and stitch” wire bonding tool. Molding compound (MC) 332 encapsulates the chip mount pad 302, the IC chip 322, the bond wires 324, 326, 328, and 330, and the heads and a portion of the upper first straight segments 314 of the leads 304, 306, 308, and 310. The middle segment, here shown as curved “S”-shaped segments 316, and the second straight segments 318 of the leads 304, 306, 308 and 310 are not encapsulated with MC 332. The underside (as oriented in FIG. 3) of the second straight segments 318 are coplanar with the underside (as oriented in FIG. 3) of the packaged IC chip 300 and lie adjacent to the MC 332 encapsulated IC chip 322. The second straight segments 318 can later be soldered to conductive areas (pads, or traces) on a printed circuit board (PCB) (not shown in FIG. 3) to electrically connect the packaged IC chip 300 to other circuitry. Note that while the molding compound 332 “encapsulates” the IC chip 322 and portions of the leads 304, 306, 308, 310, the molding compound MC 332 does not completely cover all portions of the leads, the second straight segments and portions of the middle segments such as 316, 318 of lead 304 extend from and are exposed from the molding compound 332. The exposed portions of the leads provide external terminals for the completed device and allow for physical mounting of and electrical connection to the device.

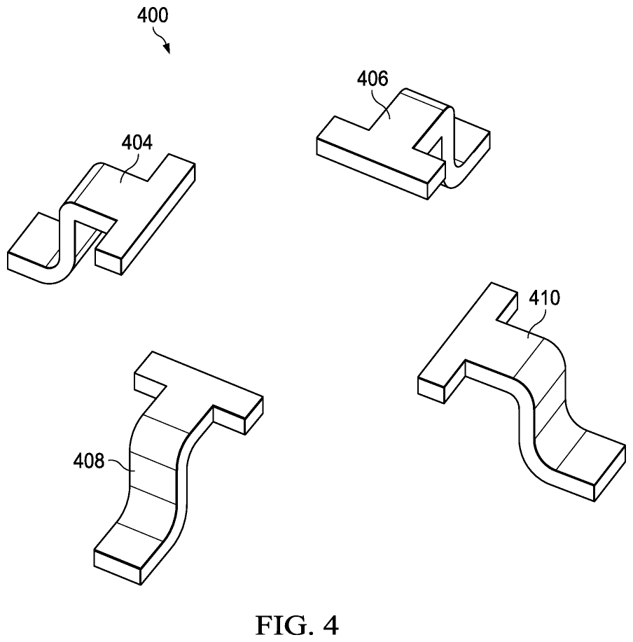

FIG. 4 is a projection view of another example lead frame 400. This lead frame 400 consists of a plurality of leads, 404, 406, 408, and 410. The number of leads usually is equal to or less than the number of bond pads on an IC chip. Four leads are used in FIG. 4 for illustration. Integrated circuits in practical applications including the arrangements described herein can have from one to several hundred leads. The leads 404, 406, 408, 410 are electrically isolated from each other.

A projection view of an IC chip mounted on the lead frame 400 described in FIG. 4 is illustrated in FIG. 5. In FIG. 5, similar reference labels are used for similar elements shown in FIG. 4. For example, lead 510 in FIG. 5 corresponds to lead 410 in FIG. 4. IC chip 522 is flip-chip mounted (mounted circuit side down) on the lead frame 500. Ball bonds 524, 526, 528, and 530 electrically connect bond pads on the IC chip 522 to the heads of leads, 504, 506, 508, and 510 respectively. The IC chip 522, the ball bonds 524, 526, 528, and 530, and the heads and a portion of the first straight segments 514 of the leads 504, 506, 508, and 510 are encapsulated with MC (not shown) to form a packaged IC similar to packaged IC 300 in FIG. 3. The lead shapes shown in this application are examples, other lead shapes, for example a lead without a T shaped head, can be used with the arrangements.

In examples, the addition of lead lock structures to the heads and first straight segments of the leads by mechanical deformation or stamping significantly improves the mechanical bond between the lead and the molding compound. The mechanical deformation of the leads produces lead locks that reduce delamination failures and significantly reduce IC package failure with little or no additional cost. Formation of the lead lock structures by mechanical deformation or stamping is performed when the lead frame is manufactured from a sheet of lead frame metal. Alternatively, lead locks can be formed by mechanical deformation in a separate stamping operation after the lead frame is formed.

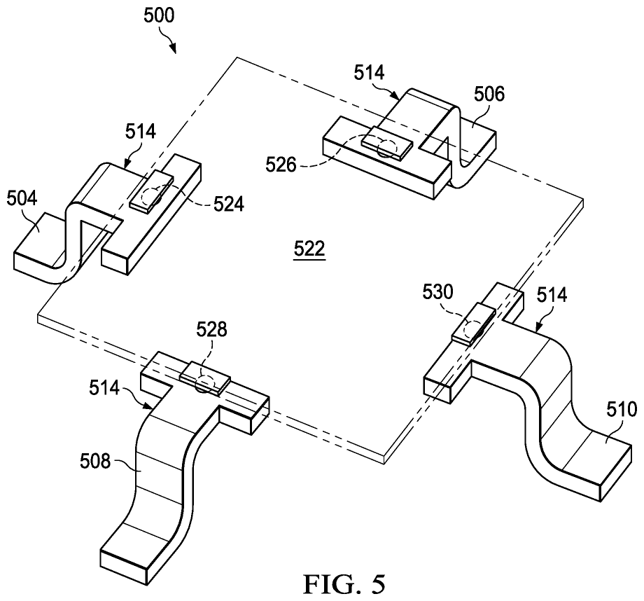

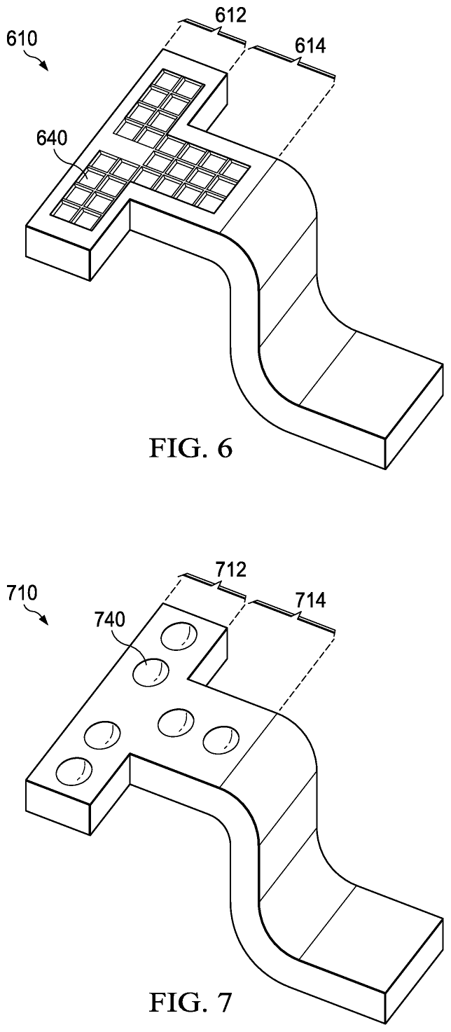

FIGS. 6-13 illustrate examples of lead lock structures. These examples illustrate the concepts. The lead lock structures are formed by mechanical deformation of the lead without forming openings or holes in the leads. The mechanical deformation can be done when the leads are manufactured, when the lead frame is manufactured, or in a subsequent step performed later.

FIG. 6 shows a lead 610 with a waffle pattern 640 formed by mechanical deformation (stamped) into a first (top as oriented in FIG. 6) surface of the head 612 and stamped into a first (top as oriented in FIG. 6) surface of the first straight segment 614 of the lead 610. The waffle pattern 640 may also be stamped on a second (bottom as oriented in FIG. 6) surface of the head 612 and a second (bottom as oriented in FIG. 6) surface of the first straight segment 614.

FIG. 7 shows a lead 710 with dimples 740 formed by mechanical deformation or stamped into the first (top as oriented in FIG. 7) surface of the head 712 and the first (top as oriented in FIG. 7) first straight segment 714 that are encapsulated with MC during packaging. The dimple pattern of dimples 740 may also be stamped into a second (bottom as oriented in FIG. 7) surface of head 712 and a second (bottom as oriented in FIG. 7) surface of the first straight segment 714.

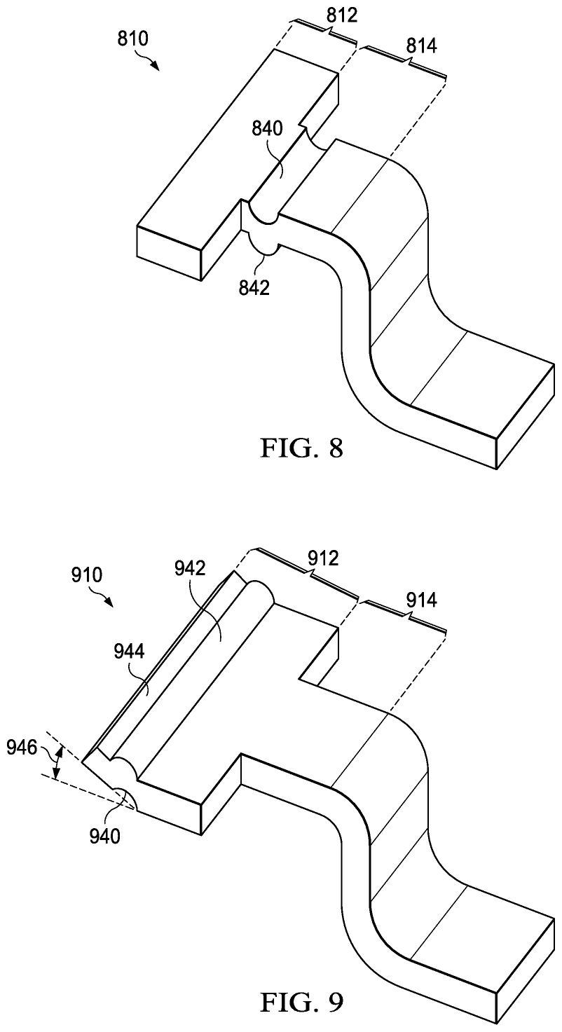

FIG. 8 shows a lead 810 with a semicircular trench 840 formed by mechanical deformation (stamped) into and across (from a first side to a second side) of the first (top as oriented in FIG. 8) surface of the first straight segment 814 that is encapsulated with MC during packaging. The semicircular trench 840 stamped into the first (top as oriented in FIG. 8) surface of the first straight segment 814 raises a semicircular mound 842 on the second (bottom as oriented in FIG. 8) surface of the first straight segment 814 opposite to the semicircular trench 840. Alternatively, the semicircular trench 840 can be stamped into the second (bottom as oriented in FIG. 8) surface of the first straight segment 814.

FIG. 9 shows a lead 910 with a semicircular trench 940 stamped lengthwise into the second (bottom as oriented in FIG. 9) surface of the head 912. The semicircular trench 940 stamped into the second (bottom as oriented in FIG. 9) surface of the head 914 raises a semicircular mound 942 on the first (top as oriented in FIG. 9) surface of the head 912 opposite to the semicircular trench 940. In addition, a portion of the head between a center of the semicircular trench 940 and the long edge of the T-shaped head 912 is bent towards the first surface (upward as oriented in FIG. 9) at an angle between about 30 degrees and about 60 degrees.

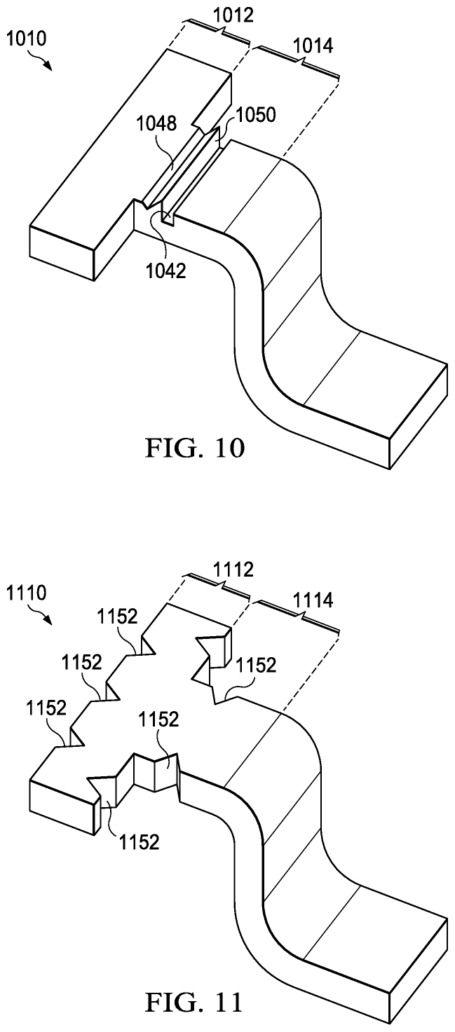

FIG. 10 shows a lead 1010 with rectangular trench 1042 and with a v-groove 1048 stamped across the width of the upper surface (top surface as oriented in FIG. 10) first straight segment 1014. Lead frame material mechanically deformed or stamped from the rectangular trench 1042 and mechanically deformed or stamped from the v-groove 1048 forms a ridge 1050 of lead frame material between the rectangular trench 1042 and the v-groove 1048 on the upper surface (top surface as oriented in FIG. 10) of the first straight segment 1014.

FIG. 11 shows a lead 1110 with a plurality of vertical v-grooves 1152 formed by mechanical deformation (stamped) into the vertical sides of the head 1112 and with a plurality of vertical v-grooves 1152 formed by mechanical deformation (stamped) into the vertical sides of the first straight segment 1114.

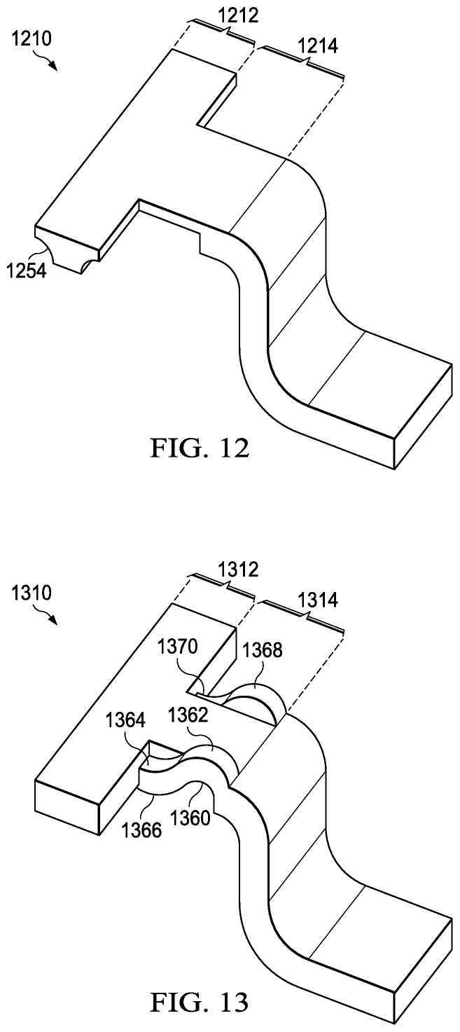

FIG. 12 shows a lead 1210 with a semicircular trench 1254 stamped into the bottom (as oriented in FIG. 12) corner edges of the head 1212 and into the bottom (as oriented in FIG. 12) corner edges of the first straight segment 1214. In the example, a first side of the semicircular trench 1254 is stamped a depth approximately half the thickness of the head 1212 and approximately an equal depth into the width of the head 1212. The semicircular trench 1254 is similarly stamped into the bottom (as oriented in FIG. 12) corner edges of the first straight segment 1214. Alternatively, a v-shaped groove could be stamped into the bottom (as oriented in FIG. 12) corner edges of the head 1212 and the bottom (as oriented in FIG. 12) corner edges of the first straight segment 1214 instead of the semicircular trench 1254.

FIG. 13 shows a lead 1310 with a first semicircular trench 1360 which extends from a first vertical side with a first horizontal depth about 20% to 30% the width of the first straight segment 1314 stamped into a first (bottom as oriented in FIG. 13) side of the first straight segment 1314. The first semicircular trench 1360 is formed by mechanical deformation or stamped to a first vertical depth in the range of about 25% to 75% the thickness of the first straight segment 1314. The first semicircular trench 1360 causes a first semicircular mound 1362 to be raised on the opposite (top as oriented in FIG. 13) side of the first straight segment 1314. A second semicircular trench 1364 is stamped adjacent to the first semicircular mound 1362 into the first vertical side with the first horizontal depth and with the first vertical depth. The second semicircular trench 1364 causes a second semicircular mound 1366 to be raised on the opposite (bottom as oriented in FIG. 13) side of the first straight segment 1314 adjacent to the first semicircular trench 1360.

A third semicircular trench (not shown) which extends from a second vertical side with a second horizontal depth about 20% to 30% the width of the first straight segment 1314 is stamped into the first (bottom as oriented in FIG. 13) side of the first straight segment 1314. The third semicircular trench (not shown) is stamped to a second vertical depth in the range of about 25% to 75% the thickness of the first straight segment 1314. The third semicircular trench causes a third semicircular mound 1368 to be raised on the opposite (top as oriented in FIG. 13) side of the first straight segment 1314. A fourth semicircular trench 1370 is stamped adjacent to the third semicircular mound 1368 into the first straight segment 1314 with the second horizontal depth and with the second vertical depth. The fourth semicircular trench 1370 causes a fourth semicircular mound to be raised on the opposite (bottom as oriented in FIG. 13) side of the first straight segment 1314 adjacent to the third semicircular trench.

The lead lock structures formed by mechanical deformation or stamped into the leads improve the mechanical bond between the lead and MC reducing delamination and eventual packaged IC failure. Mechanical deformation adds topography to the lead without the removal of metal that weakens the lead.

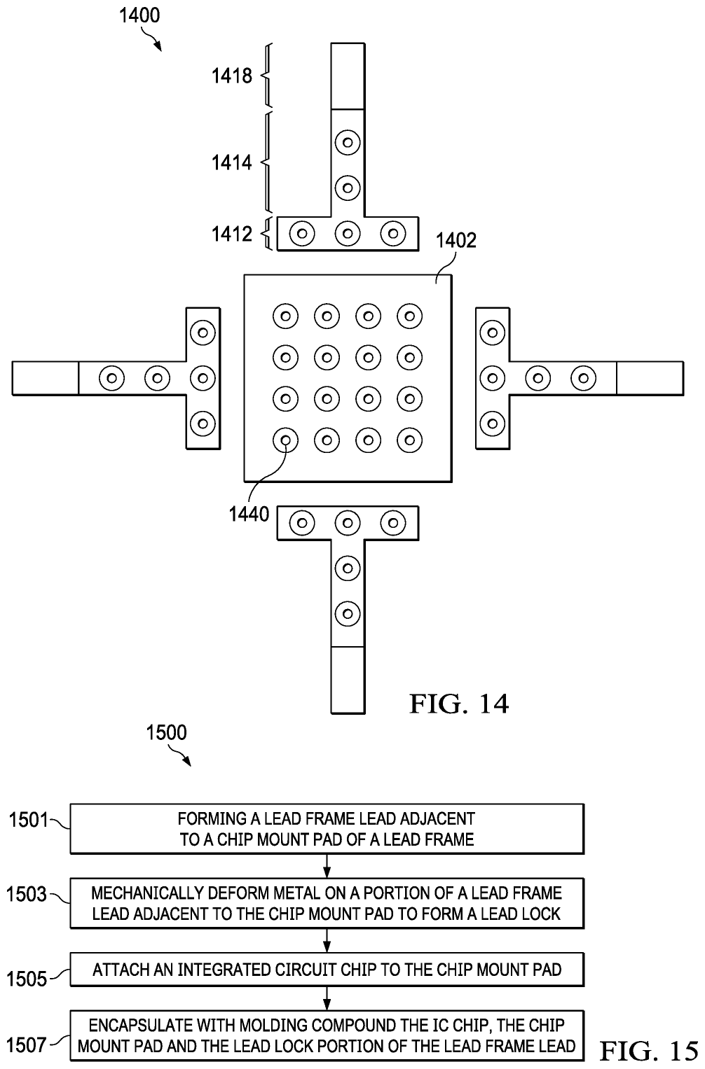

FIG. 14 is a plan view of the underside of a lead frame 1400. The underside is opposite to the topside of the lead frame 1400 on which an IC chip is mounted. In FIG. 14 similar reference labels are used for similar elements shown in FIG. 1, for clarity. For example, chip mount pad 1402 in FIG. 14 corresponds to chip mount pad 102 in FIG. 1.

As is illustrated in FIG. 14, in addition to stamping adhesion promoting structures 1440 into the underside of the head 1412 and the underside of the first straight segments 1414, adhesion promoting structures 1440 can also be stamped into the underside of the chip mount pad 1402. This improves adhesion between molding compound of the IC package and the chip mount pad 1402 additionally improving reliability of the packaged integrated circuit.

Shown in FIG. 14 are circular adhesion promoting structures 1440. Any shape adhesion promoting structures 1440 can be used and these additional shapes form additional example arrangements.

Shown in FIG. 14 the adhesion promoting structures 1440 on the chip mount pad 1402 and on the leads are the same. Different adhesion promoting structures 1440 may be used on the underside of the chip mount pad 1402.

FIG. 15 is flow diagram illustrating a method 1500 for the formation of an integrated circuit with lead locks formed using mechanical deformation. In FIG. 15, in first step 1501, a lead is formed adjacent to a chip mount pad of a lead frame. The next step at 1503 is to form lead locks on the portion of the leads adjacent to the chip mount pad using stamping or mechanical deformation. The mechanical deformation process can be performed during the manufacture of the lead frame from a sheet of lead frame metal or the lead frame can first be formed and later transferred to a stamping machine that forms the lead locks by deforming the metal of the leads later becomes embedded in molding compound.

The third step 1505 in the method of FIG. 15 is to attach an integrated circuit chip to the chip mount pad.

The fourth step 1507 in the method of FIG. 15 is to surround or embed with molding compound the integrated circuit and the portion of the leads adjacent to the chip mount pad that include the lead lock structure. The leads are not entirely encased with the molding compound, as described hereinabove, the ends of the leads extend from the package boundary formed by the molding compound and provide terminals for making physical connection and electrical connection to the integrated circuit. The lead locks improve the strength of the bond between the molding compound and leads reducing failure and improving reliability.

In an alternative method, a lead frame with lead lock structures is formed. The lead frame can subsequently be used to package an integrated circuit device as described hereinabove. A lead frame having leads and an integrated circuit mounting pad is provided. The leads are adjacent the integrated circuit mounting pad as described hereinabove. Lead locks are formed in the leads by mechanical deformation of a portion of the leads. The mechanical deformation can include stamping a pattern into the portion of the leads. There is no opening formed that extends through the leads. The lead frame with lead lock structures can then be used in the method of FIG. 15, for example, to complete a packaged integrated circuit.

Modifications are possible in the described arrangements, and other alternative arrangements are possible within the scope of the claims. For example, leads with shapes that vary from the example shapes disclosed herein can form additional arrangements with lead locks formed by mechanical deformation of the leads as discussed hereinabove.

What is claimed is:

1. A packaged integrated circuit (IC), comprising:
a lead and an IC chip mount pad;
a first portion of the lead adjacent to the IC chip mount pad deformed to form a lead lock, wherein the first portion of the lead form a T shape from a top view of the packaged IC, and includes a head portion coupled to a first straight segment that extends away from the head portion;
an integrated circuit (IC) chip mounted on a first side of the IC chip mount pad, and wherein the IC chip is electrically connected to a top surface of the head portion, the top surface of the head portion and a first surface of the first straight segment being coplanar;
the IC chip, the IC chip mount pad, and the first portion covered in molding compound; and
a second portion of the lead connected to the first straight segment, the second portion not covered in molding compound, and extends from a periphery of the packaged IC, wherein the lead lock includes a semicircular trench across a width of the first straight segment of the lead and a semicircular mound on a second surface of the first straight segment of the lead opposing the semicircular trench.

2. The packaged IC of claim 1, further including a section of the first portion from a middle of the semicircular trench bent with an angle with respect to a plane along the first portion.

3. The packaged IC of claim 2, wherein the angle is between about 30 degrees and 60 degrees.

4. The packaged IC of claim 1 wherein the lead lock further includes mechanical deformations on a second side of the IC chip mount pad.

5. The packaged IC of claim 1 wherein there are no openings extending through the lead.

6. A packaged integrated circuit (IC), comprising:
a lead and an IC chip mount pad;
a first portion of the lead adjacent to the IC chip mount pad deformed, wherein the first portion of the lead form a T shape from a top view of the packaged IC, and include a head portion coupled to a first straight segment that extends away from the head portion;
an integrated circuit (IC) chip mounted on a first side of the IC chip mount pad, and wherein the IC chip is electrically connected to a portion of a top surface of the head portion, the portion of the top surface of the head portion and a surface of the first straight segment being coplanar;
the IC chip, the IC chip mount pad, and the first portion covered in molding compound; and
a second portion of the lead connected to the first straight segment, the second portion not covered in molding compound, and extends from a periphery of the packaged IC, wherein the lead lock includes a recess across a width of the first straight segment of the lead and a projection on a second surface of the first straight segment of the lead opposing the semicircular trench.

7. The packaged IC of claim 6, wherein the recess includes a semicircular trench shape.

8. The packaged IC of claim 6, wherein the projection includes a semicircular shape.

9. The packaged IC of claim 6, wherein the recess includes sidewalls at right angles with a bottom of the recess.

10. A packaged integrated circuit (IC), comprising:
a lead and an IC chip mount pad;
a first portion of the lead adjacent to the IC chip mount pad deformed, wherein the lead includes a head portion coupled to a first straight segment that extends away from the head portion, and wherein the lead includes a first array of dimples in a first surface of the head portion of the lead and further includes a second array of dimples in a first surface of the first straight segment;
an integrated circuit (IC) chip mounted on a first side of the IC chip mount pad, and wherein the IC chip is electrically connected to the first surface of the head portion, the first surface where the IC chip is electrically connected to, and a surface of the first straight segment being coplanar;
the IC chip, the IC chip mount pad, and the first portion covered in molding compound; and
a second portion of the lead connected to the first straight segment, the second portion not covered in molding compound, and extends from a periphery of the packaged IC, wherein a surface of the second portion is coplanar with the first surface where the IC chip is electrically connected to, and with a surface of the first straight segment, and wherein the lead lock includes a recess and a projection across a width of the first straight segment of the lead.

11. The packaged IC of claim 10, wherein the first portion of the lead form a T shape from a top view of the packaged IC.

12. The packaged IC of claim 10, wherein the IC chip is electrically connected via a bond wire.

13. The packaged IC of claim 10, the recess includes sidewalls at right angles with a bottom of the recess.

14. The packaged IC of claim 10, the projection includes two sections at an acute angle with respect to each other.
